(19) United States
(12) Patent Application Publication
(10) Pub. No.: US 2017/0204509 A1
(43) Pub. Date: Jul. 20, 2017

(54) SUBSTRATE PROCESSING APPARATUS AND SUBSTRATE PROCESSING METHOD

(71) Applicant: ULVAC, INC., Chigasaki-shi, Kanagawa (JP)

(72) Inventors: Tetsushi FUJINAGA, Chigasaki-shi (JP); Atsuhito IHORI, Chigasaki-shi (JP); Masahiro MATSUMOTO, Chigasaki-shi (JP); Noriaki TANI, Chigasaki-shi (JP); Harunori IWAI, Chigasaki-shi (JP)

(21) Appl. No.: 15/326,031

(22) PCT Filed: Jul. 28, 2015
(86) PCT No.: PCT/JP2015/071300

§ 371 Date: Jan. 12, 2017

(30) Foreign Application Priority Data
Jul. 31, 2014 (JP) 2014-156604

(51) Int. Cl. C23C 14/34; H01J 37/32; H01J 37/34; C23C 14/50

(52) U.S. Cl. CPC C23C 14/34; C23C 14/50; H01J 37/3244; H01J 37/3411; H01J 37/32724

(57) ABSTRACT

A substrate processing apparatus includes a plasma generation unit that generates a plasma from a process gas in a plasma generation space in which a substrate is placed. The substrate processing apparatus also includes a cooling unit opposed to the substrate with a cooling space located in between. The cooling unit includes a supply port that supplies the process gas to the cooling space. The substrate processing apparatus also includes a process gas supply unit that supplies the process gas to the cooling unit. The substrate processing apparatus further includes a communication portion that communicates the cooling space and the plasma generation space to supply the process gas, which has been supplied to the cooling space, to the plasma generation space.

### RELATED APPLICATIONS

The present application is a National Phase entry of PCT Application No. PCT/JP2015/071300, filed Jul. 28, 2015, which claims priority from Japanese Patent Application No. 2014-156604, filed Jul. 31, 2014, the disclosures of which are hereby incorporated by reference herein in their entirety.

### TECHNICAL FIELD

The present invention relates to a substrate processing apparatus that processes two surfaces of a substrate and a substrate processing method.

### BACKGROUND ART

The use of, for example, film-like substrates as mount substrates on which electronic components are mounted has gradually increased over these years to reduce the weight and the thickness of electronic devices.

A thin substrate such as a film-like substrate has lower thermal resistance than a glass substrate, which is widely used in the prior art. When film formation is performed on such a thin substrate through, for example, sputtering, sputtered particles having high energy reach a surface of the substrate. This increases the temperature of the substrate surface. When the temperature of the substrate surface exceeds the tolerance temperature of the material forming the substrate, deformation or the like may occur in the substrate. Thus, when film formation is performed on a thin substrate, the film formation needs to be performed in a temperature range that does not exceed the tolerance temperature of the material forming the substrate.

A known mechanism for cooling a thin substrate, for example, brings a cooling roller into planar contact with a rear side of the substrate (e.g., refer to patent document 1).

### SUMMARY OF THE INVENTION

For example, when double-surface film formation is performed, collection of foreign matter on two surfaces of a substrate needs to be limited. As described above, when cooling the substrate by bringing the substrate into planar contact with the cooling roller, foreign matter tends to collect on the rear surface of the substrate, which is in contact with the cooling roller. Such a shortcoming is not limited to an apparatus in which a thin substrate is the processing subject and also occurs in a substrate processing apparatus that needs to cool a substrate.

It is an object of the present invention to provide a substrate processing apparatus and a substrate processing method that are capable of cooling a substrate while limiting collection of foreign matter on the substrate.

One aspect of the present invention is a substrate processing apparatus. The substrate processing apparatus includes a plasma generation unit that generates a plasma from a process gas in a plasma generation space in which a substrate is placed, a cooling unit opposed to the substrate with a cooling space located in between and includes a supply port that supplies the process gas to the cooling space, a process gas supply unit that supplies the process gas to the cooling unit, and a communication portion that communicates the cooling space and the plasma generation space to supply the process gas, which has been supplied to the cooling space, to the plasma generation space.

Another aspect of the present invention is a substrate processing method. The substrate processing method includes placing a substrate in a plasma generation space, and processing the substrate while cooling the substrate by supplying a process gas to a cooling space from a cooling unit that is opposed to the substrate with the cooling space located in between, wherein the substrate is processed by supplying the process gas, which has been supplied to the cooling space, to the plasma generation space through a gap formed between the substrate and the cooling unit and generating a plasma from the process gas.

In the substrate processing apparatus and the substrate processing method, the substrate is cooled by the gas supplied to the cooling space between the cooling unit and the substrate. This limits the collection of foreign matter on the substrate as compared to when a substrate is cooled by a planar contact with a cooling unit. Additionally, the cooling gas is the process gas, which is the raw material of the plasma, and supplied to the plasma generation space through the cooling space. Thus, the cooling gas is effectively used as the plasma generating gas.

In the substrate processing apparatus, preferably, the cooling unit includes a base that includes a gas channel, the gas channel includes the supply port, and the substrate processing apparatus further includes a cooling source connected to the base.

In the above structure, the base is cooled by the cooling source. Thus, the process gas, which passes through the gas channel of the base, is also cooled. This increases an effect for cooling the substrate.

In the substrate processing apparatus, preferably, the cooling unit includes a substrate-opposing surface, and the supply port is one of a plurality of supply ports symmetrically arranged about a center point of the substrate-opposing surface.

In the above structure, the process gas is supplied from the supply ports that are symmetrically arranged about the center point of the substrate-opposing surface. This reduces unevenness in the amount of the process gas supplied to the cooling space thereby limiting local cooling of the substrate. Thus, a uniform temperature distribution is obtained in the surface of the substrate.

In the substrate processing apparatus, preferably, the cooling unit includes a rectangular substrate-opposing surface, the substrate-opposing surface includes a plurality of regions defined by a diagonal line, and the supply port has the same open area in each of the regions.

In the above structure, the supply port has the same open area in each of the regions, which are defined by the diagonal line of the substrate-opposing surface. This reduces unevenness in the amount of the process gas supplied to the cooling space. Also, the process gas is supplied from the cooling space to the plasma generation space in an isotropic manner.

Preferably, the substrate processing apparatus further includes a frame-shaped substrate holder that holds the substrate, and the cooling unit includes a substrate-opposing surface that is smaller than an opening defined in an inner side of the substrate holder.

In the above structure, the substrate-opposing surface is smaller than the inner opening of the substrate holder. Thus, when the cooling unit approaches the opening, the relative distance from the substrate is shortened without interfering with the substrate holder. Thus, the cooling unit cools the substrate in a more effective manner.

Preferably, the substrate processing apparatus further includes a frame-shaped substrate holder that holds the substrate. The substrate holder includes a frame and a substrate fastener. The substrate fastener is arranged on the frame to fasten the substrate. The substrate fastener is configured to form a gap between the frame and the substrate so that the substrate fastener allows the process gas to be supplied from the cooling space to the plasma generation space through the gap.

In the above structure, the process gas, which has been supplied to the cooling space, is supplied to the plasma generation space through the gap between the frame and the substrate. This limits warping of the substrate caused by pressure of the process gas. Consequently, the flow rate of the process gas to the cooling space may be increased to increase the cooling effect of the substrate.

In the substrate processing apparatus, preferably, the cooling unit includes a substrate-opposing surface and ribs. The ribs project from the substrate-opposing surface. The substrate processing apparatus further includes a communication port located between the ribs to supply the process gas from the cooling space to the plasma generation space.

In the above structure, the ribs arranged on the substrate-opposing surface prolong the time during which the process gas remains in the cooling space. Additionally, the communication port is located between the ribs. This allows for control of the direction in which the process gas flows to the plasma generation space.

### BRIEF DESCRIPTION OF THE DRAWINGS

FIG. 1 is a schematic side view illustrating the structure of a first embodiment of a substrate processing apparatus.

FIG. 2 is a schematic diagram illustrating a transport mechanism of the substrate processing apparatus illustrated in FIG. 1.

FIG. 3 is a perspective view illustrating a substrate holder and a film substrate attached to the substrate holder of the substrate processing apparatus illustrated in FIG. 1.

FIG. 4 is a cross-sectional view illustrating a portion of the substrate holder illustrated in FIG. 3.

FIG. 5 is a perspective view of the substrate holder and a cooling unit in the first embodiment.

FIG. 6 is a cross-sectional view of the substrate holder and the cooling unit in the first embodiment.

FIG. 7 is a perspective view of a substrate holder and a cooling unit in a second embodiment.

FIG. 8 is a cross-sectional view of the substrate holder and the cooling unit in the second embodiment.

FIG. 9 is a cross-sectional view illustrating a portion of a cooling unit in a third embodiment.

FIG. 10 is a front view illustrating a modified example of a cooling unit.

FIG. 11 is a front view illustrating a modified example of a cooling unit.

FIG. 12 is a front view illustrating a modified example of a cooling unit.

FIG. 13 is a front view illustrating a modified example of a cooling unit.

FIG. 14 is a front view illustrating a modified example of a cooling unit.

FIG. 15 is a front view illustrating a modified example of a cooling unit.

FIG. 16 is a front view illustrating a modified example of a substrate holder.

### DESCRIPTION OF THE EMBODIMENTS

### First Embodiment

A first embodiment of a substrate processing apparatus will now be described. The substrate processing apparatus of the present embodiment is a sputtering device that forms a thin film on a substrate through sputtering. The substrate that is subject to film formation is a film-like substrate (hereafter, referred to as film substrate).

The main component of the film substrate is a resin. The film substrate of the present embodiment is square and has sides, each of which has a length of, for example, 500 mm to 600 mm. The thickness of the film substrate is, for example, 1 mm or less.

### [Schematic Structure of Substrate Processing Apparatus]

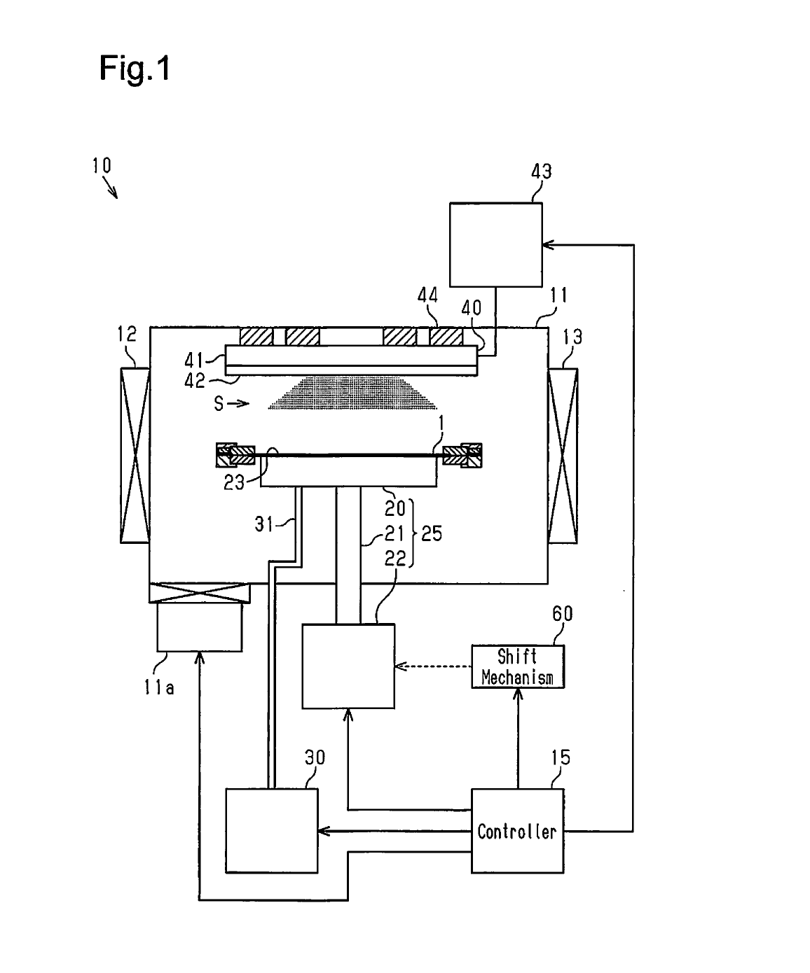

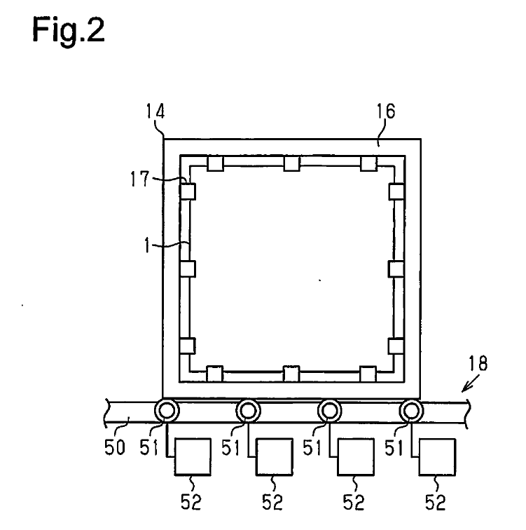

The schematic structure of a substrate processing apparatus 10 will now be described with reference to FIGS. 1 and 2.

As illustrated in FIG. 1, the substrate processing apparatus 10 includes gate valves 12, 13, which are respectively located at a loading side and an unloading side of a chamber 11. A transport passage is located between the gate valves 12, 13 to transport a film substrate 1. The gate valves 12, 13 may be omitted depending on the specification of the substrate processing apparatus 10.

The chamber 11 is connected to a vent 11a, which discharges the gas out of the chamber 11. The vent 11a is, for example, a turbomolecular pump and controlled by a controller 15, which is located beside the substrate processing apparatus 10.

The chamber 11 includes a cooling unit 20, which is located at one side of the transport passage. The cooling unit 20 is plate-like and includes a square substrate-opposing surface 23, which is located at a transport passage side.

The cooling unit 20 is connected by a connection portion 21 to a cryopump 22, which is a cooling source. The cryopump 22 is located outside the chamber 11. The connection portion 21, which connects the cooling unit 20 and the cryopump 22, is formed from a material having a high thermal conductivity such as a metal. Further, the connection portion 21 is movable in an insertion portion formed in a wall of the chamber 11. Instead of the cryopump, the cooling source of the cooling unit 20 may be a mechanism or the like that cools the cooling unit 20 by drawing a cooling medium of an ultralow temperature into the cooling unit 20.

The cryopump 22 includes a freezer unit (not illustrated) or the like and includes an ultralow temperature surface that becomes an ultralow temperature of, for example, −150° C. to −100° C. The connection portion 21 includes one end, which is connected to the ultralow temperature surface of the cryopump 22, and the other end, which is connected to a bottom surface of the cooling unit 20. Thus, the temperature of the cooling unit 20 is lowered to an ultralow temperature range by transmitting heat from the cooling unit 20 to the cryopump 22 through the connection portion 21. The cryopump 22 is controlled by the controller 15.

The cooling unit 20, the connection portion 21, and the cryopump 22 form a cooling mechanism 25. The cooling mechanism 25 is coupled to a shift mechanism 60. The shift mechanism 60 includes a motor (not illustrated) or the like as a drive source. The motor is controlled by the controller 15. The shift mechanism 60 is driven to shift the cooling unit 20 between a cooling position where the cooling unit 20 is located proximate to the film substrate 1 and a retracted position where the cooling unit 20 is separated from the film substrate 1 by a relatively large distance. In the present embodiment, the cooling unit 20 is shifted. Instead, a substrate holder 14, which holds the film substrate 1, may be shifted relative to the cooling unit 20.

The cooling unit 20 is also connected by a gas supply pipe 31 to a process gas supply unit 30, which supplies a process gas. The process gas, which is the raw material gas of the plasma, may be, for example, any one of argon, nitrogen gas, oxygen gas, and hydrogen gas. Alternatively, the process gas may be a mixture of at least two of the four gasses including argon. The process gas supply unit 30 includes a flow rate adjustment valve, which adjusts the flow rate of the process gas. The controller 15 controls the process gas supply unit 30 to start or stop the supply of the process gas and also adjust the flow rate of the process gas.

A cathode unit 40, which functions as a plasma generation unit, is located at the other side of the transport passage. The cathode unit 40 includes a backing plate 41 and a target 42. The target 42, which is formed from the main component of a thin film that is the subject of formation, is located on a surface of the backing plate 41 that is located toward the cooling unit 20.

The backing plate 41 is electrically connected to a target power supply 43. Magnetic circuits 44 are located at a rear surface of the backing plate 41 to generate a magnetic field in a plasma generation space S. The magnetic circuits 44 generate the magnetic field in the plasma generation space S at a location close to the cathode unit 40. The magnetic field, which is generated by the magnetic circuits 44, captures electrons in the plasma and increases the rate of collisions of the electrons with atoms or molecules of a sputter gas. This increases the density of the plasma.

As illustrated in FIG. 2, the transport passage 18 includes a transport rail 50 and transport rollers 51. Each transport roller 51 is connected to a transport motor 52, which is controlled by the controller 15. The transport rollers 51 support one side (bottom portion) of the substrate holder 14, to which the film substrate 1 is attached, to transport the film substrate 1 in a substantially vertical position.

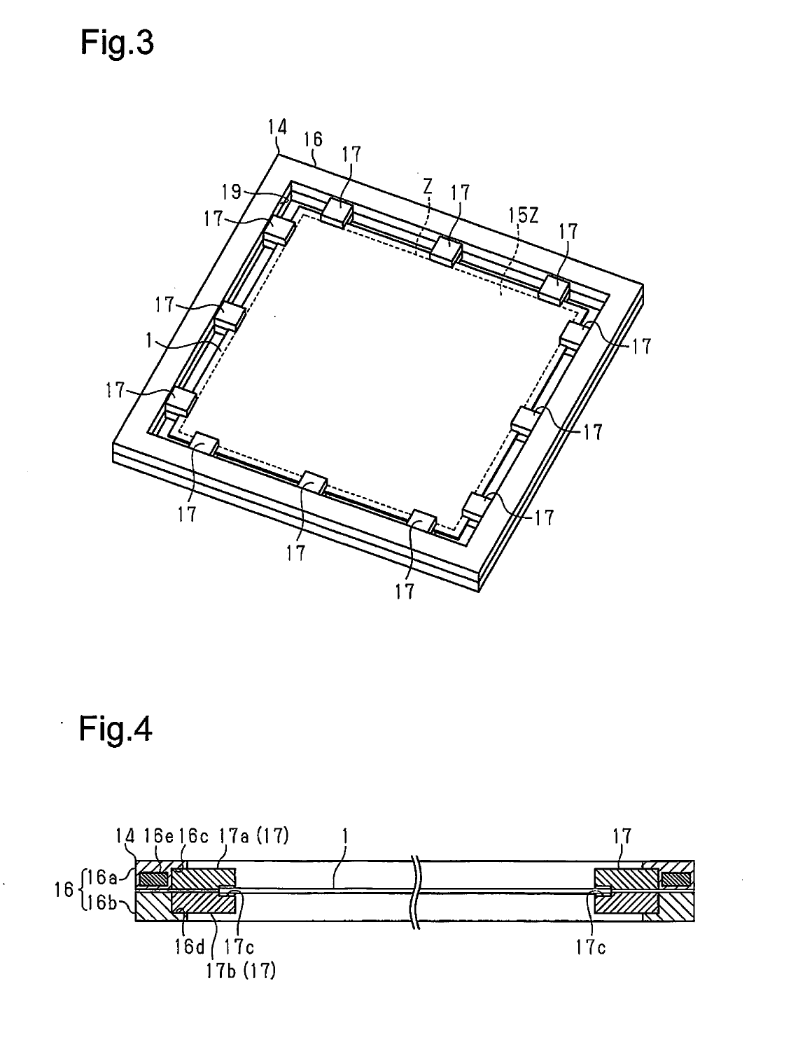

The substrate holder 14, which holds the film substrate 1, will now be described with reference to FIGS. 3 and 4.

As illustrated in FIG. 3, the substrate holder 14 includes a frame 16 and substrate fasteners 17, which are arranged on inner surfaces of the frame 16. The substrate fasteners 17 are formed by magnets and arranged on the four sides of the frame 16.

As illustrated in FIG. 4, the frame 16 includes a first frame 16a and a second frame 16b. Groove-shaped engaged portions 16c, 16d are formed at inner sides of the first frame 16a and the second frame 16b, respectively. The first frame 16a and the second frame 16b are fastened to each other by a fastener (not illustrated) or the like. Magnets 16e are embedded in the first frame 16a at positions where the substrate fasteners 17 are located or through the entire region of the first frame 16a. Each substrate fastener 17 includes two fastening pieces 17a, 17b. The substrate fastener 17 includes one end that includes a groove 17c. The groove 17c receives an edge of the film substrate 1. The groove 17c may be omitted depending on the thickness of the film substrate 1.

When attaching the film substrate 1 to the substrate holder 14, for example, the fastening pieces 17b of the substrate fasteners 17 are arranged in the engaged portion 16d of the second frame 16b, and the film substrate 1 is located at a predetermined position relative to the second frame 16b. The fastening pieces 17a are also arranged in the engaged portion 16c of the first frame 16a. The fastening pieces 17a are attracted toward the first frame 16a by magnetic force of the magnets 16e. The first frame 16a, on which the fastening pieces 17a are arranged, is placed on the second frame 16b where the film substrate 1 is located on the fastening pieces 17b. Consequently, the film substrate 1 is fastened to the frame 16 by the substrate fasteners 17.

A gap 19 is formed between the film substrate 1, which is attached to the substrate holder 14, and the frame 16. The inner side of the substrate fasteners 17 of the substrate holder 14 defines an opening Z, which is located at an inner side of the substrate holder 14. The film substrate 1 includes a margin, which is arranged on edges of the film substrate 1 to allow the substrate fasteners 17 to hold the film substrate 1. Each surface of the film substrate 1 includes a region exposed from the opening Z in the substrate holder 14, that is, a region located inward from the margin, defining a clean region 15Z (refer to FIG. 3) where collection of foreign matter or the like is to be limited.

### [Cooling Unit Structure]

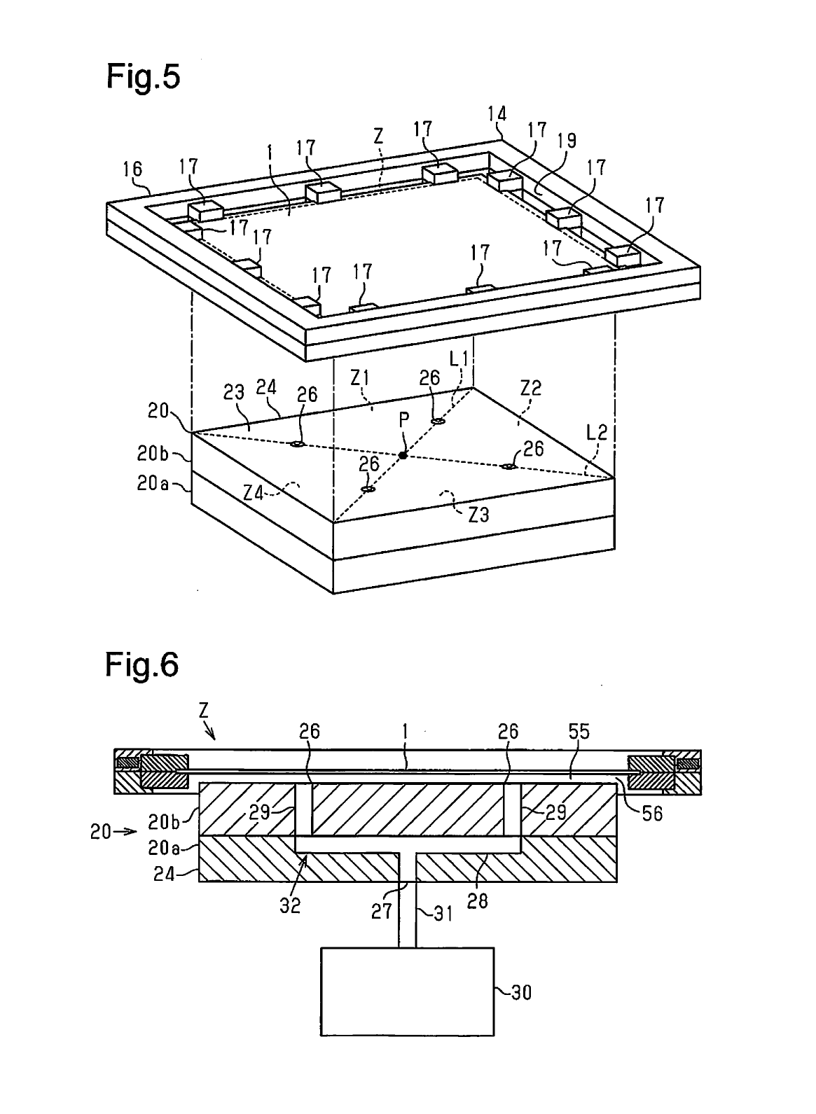

The structure of the cooling unit 20 will now be described in detail with reference to FIGS. 5 and 6.

As illustrated in FIG. 5, the cooling unit 20 includes a box-shaped base 24. The base 24 includes a substrate-opposing surface 23 at a side opposed to the cathode unit 40. The substrate-opposing surface 23 includes four open supply ports 26. The supply ports 26 are circular and arranged at positions symmetrical about a center point P of the substrate-opposing surface 23. The square substrate-opposing surface 23 is divided by diagonal lines L1, L2 into small regions Z1 to Z4. The supply ports 26 have the same open area in each of the small regions Z1 to Z4. For example, two of the four supply ports 26 are arranged in each of the diagonal lines L1, L2 of the square substrate-opposing surface 23.

As illustrated in FIG. 6, the length of one side of the substrate-opposing surface 23 is smaller than the length (width or height in a plan view) of one side defining the opening Z in the substrate holder 14. In other words, the length of one side of the substrate-opposing surface 23 is smaller than the length (width or height in a plan view) of one side of the clean region 15Z of the film substrate 1, which is held by the substrate holder 14. If the substrate-opposing surface 23 is larger than the opening Z in the substrate holder 14 or the clean region 15Z, when the cooling unit 20 approaches the film substrate 1, the substrate-opposing surface 23 interferes with the substrate fasteners 17.

When the substrate-opposing surface 23 is smaller than the opening Z in the substrate holder 14, the relative distance may be decreased between the film substrate 1 and the substrate-opposing surface 23 without interference between the substrate-opposing surface 23 and the substrate holder 14. This increases a cooling effect of the film substrate 1. For the sake of convenience, FIG. 6 illustrates the relative distance that is longer than the actual distance between the film substrate 1 and the substrate-opposing surface 23. To increase the cooling effect, it is preferred that the relative distance (proximate distance at the cooling position) be, for example, 1 mm or less between the film substrate 1 and the substrate-opposing surface 23.

The cooling unit 20 (base 24) includes an outer cooling unit 20a and an inner cooling unit 20b, which is arranged on the outer cooling unit 20a. The outer cooling unit 20a includes a gas inlet port 27, which is connected to the gas supply pipe 31, and a common channel 28. The gas inlet port 27 and the common channel 28 are formed, for example, by machining a metal member. When the outer cooling unit 20a is formed from a metal plate or the like, the gas inlet port 27 and the common channel 28 may be formed through pressing.

The inner cooling unit 20b includes the common channel 28 and branch channels 29, which connect the supply ports 26. The branch channels 29 are, for example, holes that extend through a metal member in the thickness-wise direction and located at positions that are in communication with the common channel 28. Arrangement of the inner cooling unit 20b on the outer cooling unit 20a forms a gas channel 32, which is continuous from the gas inlet port 27 through the common channel 28 and the branch channels 29 to the supply ports 26.

An adhesion layer formed from a material having a high thermal conductivity may be applied between the outer cooling unit 20a and the inner cooling unit 20b. Alternatively, the outer cooling unit 20a and the inner cooling unit 20b may be fastened to each other by local adhesion. Alternatively, a seal member may be arranged on a periphery of the cooling unit 20 between the outer cooling unit 20a and the inner cooling unit 20b. The thickness ratio of the outer cooling unit 20a to the inner cooling unit 20b is not particularly limited.

The base 24, which is connected to the cryopump 22 by the connection portion 21, is cooled to an ultralow temperature of −100° C. or below. Thus, the process gas, which passes through the base 24, is also cooled, for example, by contacting an inner wall of the channel.

### [Substrate Processing Apparatus Operation]

The operation of the substrate processing apparatus 10 will now be described with reference to FIG. 6.

When the film substrate 1, which is attached to the substrate holder 14, is loaded into the chamber 11 through the loading side gate valve 12, the controller 15 drives the transport motors 52 to transport the film substrate 1 along the transport passage 18. The controller 15 places the film substrate 1 in an opposing position, which is opposed to the cathode unit 40, and then stops the driving of the transport motors 52. The surface of the film substrate 1 at the side located closer to the cathode unit 40 is a film formation surface in the substrate processing apparatus 10, and the surface at the opposite side is a cooling subject surface, which is cooled by the cooling unit 20. In this step, the cooling unit 20 is located at the retracted position.

The controller 15 drives the shift mechanism 60 to move the entire cooling mechanism 25 toward the cathode unit 40. Consequently, the cooling unit 20 is shifted to the cooling position from the retracted position. The substrate-opposing surface 23 is opposed to the film substrate 1 with a cooling space 55 located in between. The cooling space 55 is a space defined by the substrate-opposing surface 23 and the film substrate 1 and in communication with the plasma generation space S through a communication portion 56, which is a gap formed between the cooling unit 20 and the film substrate 1.

The controller 15 also controls the vent 11a to discharge the gas out of the chamber 11. The controller 15 drives the cryopump 22. Consequently, the temperature of the cooling unit 20 is adjusted to a predetermined temperature of, for example, −100° C. or below.

Additionally, the controller 15 controls the process gas supply unit 30 to supply the process gas to the cooling unit 20. The process gas is cooled by passing through the cooled base 24. The cooled process gas is supplied from the supply ports 26 to the cooling space 55, which is formed between the cooling unit 20 and the film substrate 1.

When the process gas is supplied to the cooling space 55 and comes into contact with the cooling subject surface of the film substrate 1, the film substrate 1 is cooled. The process gas passes through the cooling space 55 while cooling the film substrate 1 and is supplied to the plasma generation space S through the communication portion 56, which is formed between the cooling unit 20 and the film substrate 1, and the gap 19, which is formed between the film substrate 1 and the frame 16.

When the process gas is supplied into the chamber 11 through the cooling unit 20 and the chamber 11 reaches a predetermined pressure, the controller 15 controls the target power supply 43 to supply high frequency power to the backing plate 41. Consequently, a plasma is generated from the process gas in the plasma generation space S. Positive ions in the plasma are attracted to the target 42, which has a negative potential. The positive ions strike the target 42 and force target particles out of the target 42. The target particles reach the film formation surface of the film substrate 1 to form a thin film of the target particles. As described above, when the thickness of the film substrate 1 is 1 mm or less, increases in the temperature of the film substrate 1 caused by sputtering are more likely to deform the film substrate 1. However, the cooling performed by the cooling unit 20 limits such deformation of the film substrate 1. When the thickness of the film substrate 1 is 100 μm or less, the deformation of the film substrate 1 is limited in a more effective manner.

When the supply of the high frequency power continues for a predetermined time, the controller 15 stops the supply of the high frequency lower to the target power supply 43. The controller 15 also stops the driving of the cryopump 22 and the supply of the process gas from the process gas supply unit 30. Further, the controller 15 drives the shift mechanism 60 to move the cooling unit 20 to the retracted position from the cooling position. Then, the controller 15 drives the transport motors 52 to unload the film substrate 1 from the chamber 11.

As described above, the film substrate 1 is cooled by the process gas that is supplied to the cooling space 55 formed between the cooling unit 20 and the film substrate 1. This limits collection of foreign matter on the film substrate 1 as compared to when the film substrate 1 is cooled by a planar contact with a cooling unit. Further, the gas used for cooling the film substrate 1 is the process gas. Thus, the cooling gas does not adversely affect a film formation step and is effectively used as the raw material gas of the plasma. Additionally, there is no need to separately arrange a gas supply system that circulates the cooling gas.

Further, the process gas is supplied to the plasma generation space S through the communication portion 56, which is a gap between the film substrate 1 and the cooling unit 20, and the gap 19, which is formed between the substrate holder 14 and the film substrate 1. This limits warping of the film substrate 1 caused by gas pressure as compared to when the cooling space is an enclosed space. Thus, for example, the flow rate of gas supplied to the cooling space 55 may be increased to increase the cooling effect of the film substrate 1.

The supply ports 26 are symmetrically arranged about the center point P of the substrate-opposing surface 23. Also, the supply ports 26 have the same open area in each of the small regions Z1 to Z4, which are defined by the diagonal lines L1, L2. This reduces unevenness in the amount of the process gas supplied to the cooling space 55 and uniformly cools the small regions Z1 to Z4. Thus, a uniform temperature distribution is obtained in the surface of the film substrate 1.

The reduced unevenness in the amount of the process gas supplied to the cooling space 55 allows for substantially uniform supply of the process gas to the plasma generation space S from the four sides of the substrate-opposing surface 23. Thus, the reduced unevenness in the amount of the process gas in the plasma generation space S obtains a uniform density of the plasma.

The above embodiment has the advantages described below.

(1) The film substrate 1 is cooled by the process gas that is supplied to the cooling space 55 formed between the cooling unit 20 and the film substrate 1. This limits collection of foreign mater on the film substrate 1 as compared to when the film substrate 1 is cooled by a planar contact of the film substrate 1 with the cooling unit 20. Further, the cooling gas is the process gas, which is the raw material gas of the plasma, and supplied to the plasma generation space S through the cooling space 55. Thus, the cooling gas is effectively used as the plasma generating gas.

(2) The base 24 is cooled by the cryopump 22, which is the cooling source. Thus, the process gas, which passes through the gas channel 32 in the base 24, is also cooled. This increases the cooling effect of the film substrate 1.

(3) The process gas is supplied from the supply ports 26, which are symmetrically arranged about the center point P of the substrate-opposing surface 23. Thus, unevenness in the amount of the process gas supplied to the cooling space 55 is reduced. This limits local cooling of the film substrate 1 and obtains a uniform temperature distribution in the surface of the film substrate 1.

(4) The substrate-opposing surface 23 includes the small regions Z1 to Z4, which are defined by the diagonal lines L1, L2. The supply ports 26 have the same open area in each of the small regions Z1 to Z4. This reduces unevenness in the amount of the process gas supplied to the cooling space 55. Additionally, the process gas is supplied from the cooling space 55 to the plasma generation space S in an isotropic manner.

(5) The substrate-opposing surface 23 is smaller than the inner opening Z of the substrate holder 14. Thus, when the cooling unit 20 approaches the opening Z, the relative distance from the film substrate 1 may be shortened without interfering with the substrate holder 14. Thus, the cooling unit 20 cools the film substrate 1 in a more effective manner.

### Second Embodiment

A second embodiment of a substrate processing apparatus 10 will now be described focusing on the differences from the first embodiment. The second embodiment of the substrate processing apparatus 10 and the first embodiment basically have the same structure. In the drawings, the same reference characters are given to those elements that are substantially the same as the corresponding elements of the first embodiment. Such elements will not be described in detail.

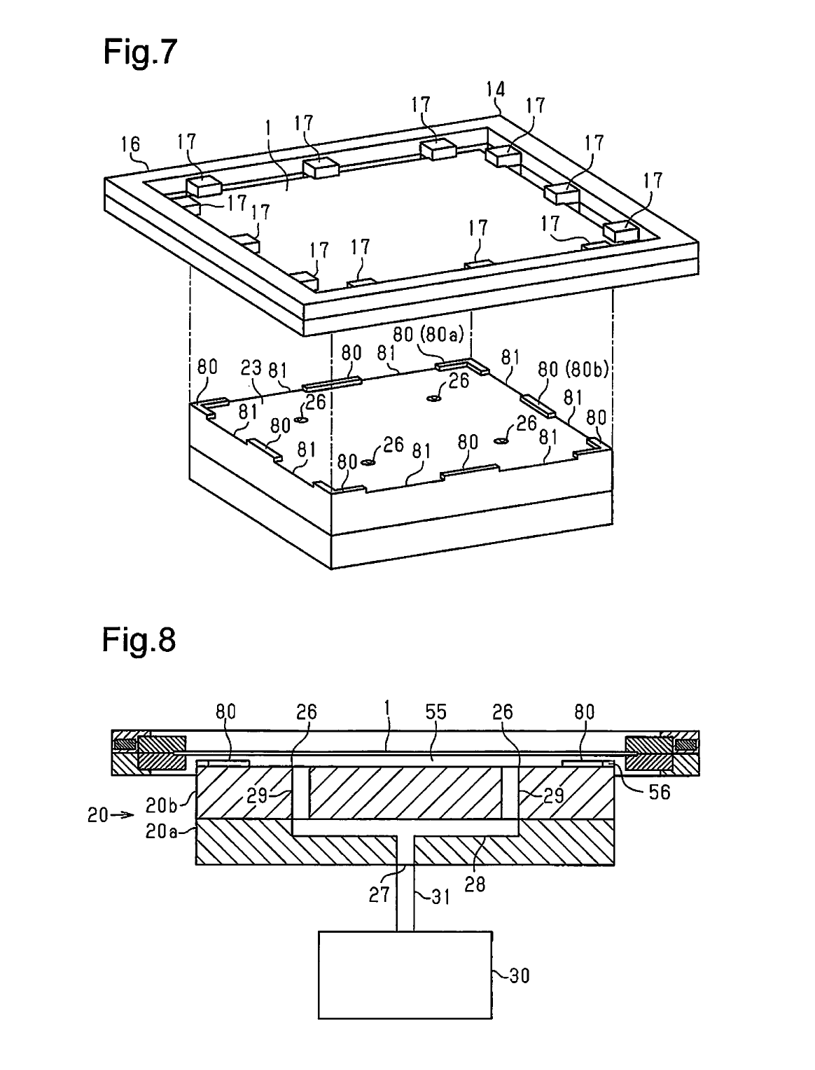

As illustrated in FIG. 7, the substrate-opposing surface 23 of the cooling unit 20 includes a plurality of ribs 80. The ribs 80 project from the substrate-opposing surface 23 and are arranged along edges of the substrate-opposing surface 23. Communication ports 81 are arranged between adjacent ones of the ribs 80 to communicate the cooling space 55 and the plasma generation space S. To increase the cooling effect, it is preferred that the relative distance (proximate distance at cooling position) be, for example, 1 mm or less between the film substrate 1 and the substrate-opposing surface 23.

Four sides of the substrate-opposing surface 23 have the same layout patterns of the ribs 80 and the communication ports 81. For example, L-shaped ribs 80a are located on four corners of the substrate-opposing surface 23, and straight ribs 80b are located between two of the L-shaped ribs 80a.

As illustrated in FIG. 8, when the cooling unit 20 is located at the cooling position, the distal end of each rib 80 is not in contact with the cooling subject surface of the film substrate 1. Much process gas supplied to the cooling space 55 passes through the communication ports 81. This controls the direction in which the process gas flows. The communication ports 81 are located at the same position of each side of the substrate-opposing surface 23. This allows for isotropic supply of the process gas from the cooling space 55 to the plasma generation space S.

As described above, the substrate processing apparatus 10 of the second embodiment has the advantage described below in addition to advantages (1) to (5).

(6) The ribs 80, which are arranged on the substrate-opposing surface 23, prolong the time during which the process gas remains in the cooling space 55. Additionally, the communication ports 81 are arranged between the ribs 80. This allows for control of the direction in which the process gas flows to the plasma generation space S.

### Third Embodiment

A third embodiment of a substrate processing apparatus 10 will now be described focusing on the differences from the first embodiment. The third embodiment of the substrate processing apparatus 10 and the first embodiment basically have the same structure. In the drawings, the same reference characters are given to those elements that are substantially the same as the corresponding elements of the first embodiment. Such elements will not be described in detail.

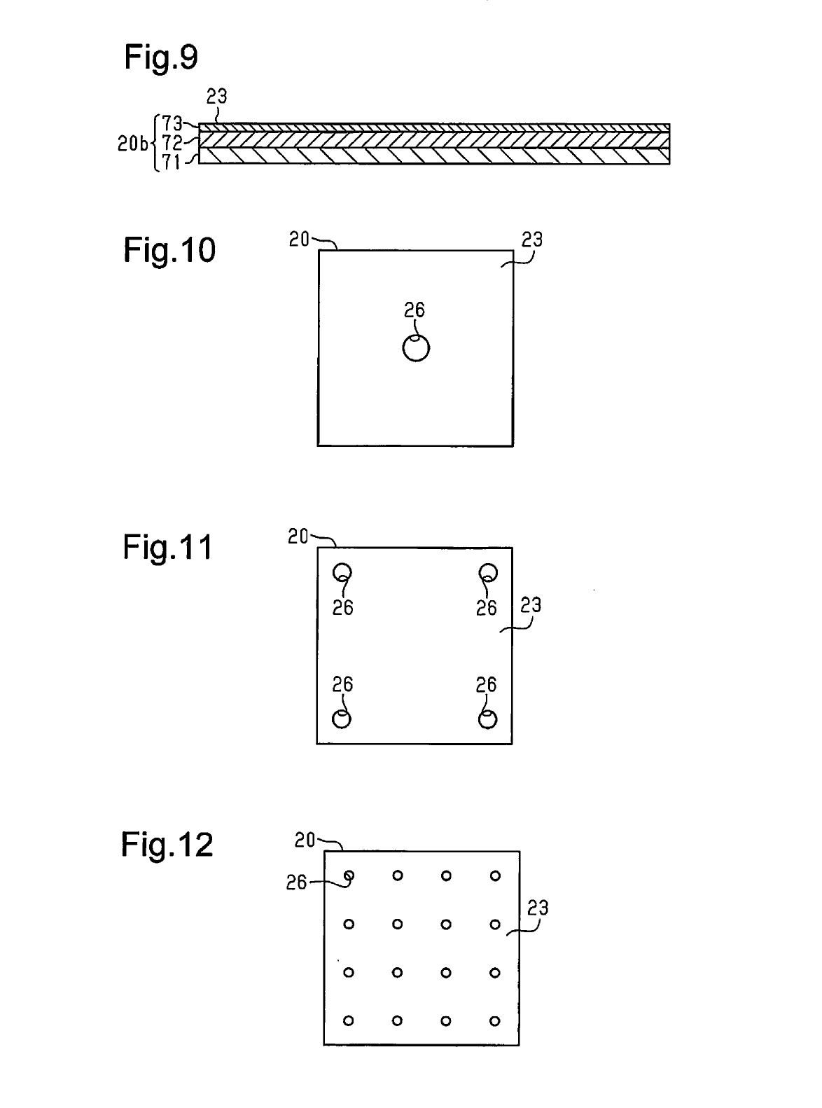

As illustrated in FIG. 9, the inner cooling unit 20b, which is included in the cooling unit 20, has a structure in which a cooling layer 71, a buffer layer 72, and a black layer 73 are sequentially stacked. The cooling layer 71 is in contact with the outer cooling unit 20a. The black layer 73 includes the substrate-opposing surface 23, which is opposed to the film substrate 1. The buffer layer 72 is located between the cooling layer 71 and the black layer 73. The thickness ratio of the cooling layer 71, the buffer layer 72, and the black layer 73 is not particularly limited and only needs to be set so as not to significantly interfere with the thermal conductivity of the outer cooling unit 20a.

The cooling layer 71 is preferably formed from a material that easily transmits the temperature of the outer cooling unit 20a and, for example, a metal such as copper. The buffer layer 72, which restricts removal of the black layer 73 form the cooling layer 71, preferably has a thermal expansion coefficient that is between the thermal expansion coefficient of the cooling layer 71 and the thermal expansion coefficient of the black layer 73.

The material forming the black layer 73 has a higher emissivity than those forming the remaining layers. The emissivity of the material forming the black layer 73 is preferably 8.0 or greater and 1 or less. The black layer 73 only needs to have a high emissivity to at least the substrate-opposing surface 23. The material forming the black layer 73 is preferably, for example, aluminum, the surface of which has an anodized coat or carbon. Alternatively, the material forming the black layer 73 may have a coating such as black chrome plating or black anodized aluminum.

The surface of the cooling unit 20 opposed to the film substrate 1 is black. This reduces heat reflected from the surface of the cooling unit 20 toward the film substrate 1 as compared to when the surface of a cooling unit has a relatively low emissivity. Thus, increases in the temperature of the film substrate 1 are limited.

As described above, the substrate processing apparatus of the third embodiment has the advantage described below in addition to advantages (1) to (5).

(7) The cooling unit 20 includes the black substrate-opposing surface 23 to reduce the heat reflected toward the film substrate 1 from the surface of the cooling unit 20. This limits increases in the temperature of the film substrate 1.

The above embodiments may be modified as follows.

As illustrated in FIG. 10, the substrate-opposing surface 23 may include one supply port 26 in a central portion. This allows for isotropic supply of the process gas from the cooling space 55 to the plasma generation space S.

As illustrated in FIG. 11, the supply ports 26 may be arranged toward the four corners of the substrate-opposing surface 23. This reduces gas pressure applied to a central portion of the film substrate 1 and limits warping of the film substrate 1.

As illustrated in FIG. 12, the substrate-opposing surface 23 may include four or more supply ports 26. The supply ports 26 are preferably arranged in the substrate-opposing surface 23 in a matrix at equal intervals or in a symmetrical manner about the center point. This obtains a uniform temperature distribution in the surface of the film substrate 1 and allows for isotropic supply of the process gas from the cooling space 55 to the plasma generation space S.

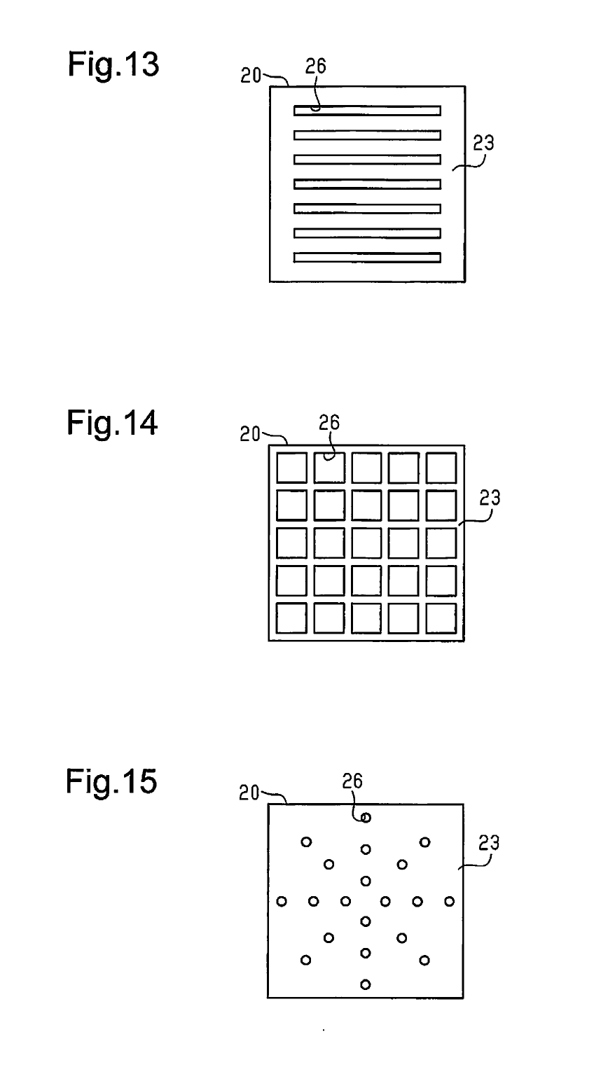

As illustrated in FIG. 13, the substrate-opposing surface 23 may include elongated supply ports 26, which extend in the width-wise direction of the substrate-opposing surface 23. This obtains a uniform temperature distribution in the surface of the film substrate 1.

As illustrated in FIG. 14, the inner cooling unit 20b of the cooling unit 20 may have a lattice structure. In this case, the outer cooling unit 20a includes, for example, a buffer chamber, which temporarily stores the process gas drawn in from the gas inlet port 27. The process gas is supplied from the buffer chamber to the supply ports 26 of the inner cooling unit 20b. This obtains a uniform temperature distribution in the surface of the film substrate 1 and allows for isotropic supply of the process gas from the cooling space 55 to the plasma generation space S.

As illustrated in FIG. 15, the supply ports 26 may be arranged in the substrate-opposing surface 23 in a concentric manner. This case obtains a uniform temperature distribution in the surface of the film substrate 1 and allows for isotropic supply of the process gas from the cooling space 55 to the plasma generation space S.

The substrate holder 14 may have a structure that differs from the above embodiments.

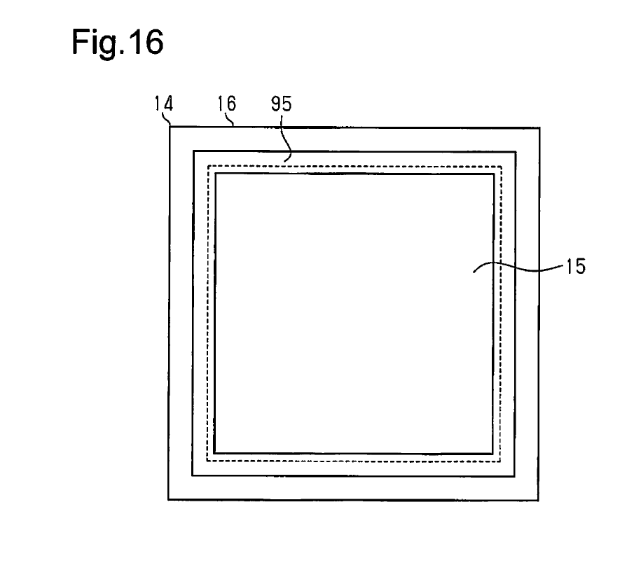

As illustrated in FIG. 16, the substrate holder 14 may include, for example, the frame 16 and a substrate fastener 95, which is tetragonal frame-shaped and arranged along inner surfaces of the frame 16. The substrate fastener 95 fastens the entire edges of the film substrate 1. Thus, the film substrate 1 is firmly fastened.

In the above embodiments, the film substrate 1 and the substrate-opposing surface 23 of the cooling unit 20 are square but may have different shapes. The film substrate 1 and the substrate-opposing surface 23 of the cooling unit 20 may be, for example, rectangular. In this case, it is also preferred that the supply ports 26 be symmetrically arranged about the center point of the substrate-opposing surface 23. Additionally, it is preferred that the supply ports 26 have the same open area in each of the small regions defined by the diagonal lines.

The substrate holder 14 is configured to include the frame 16 and the substrate fasteners 17. However, the configuration only needs to be such that film formation can be performed on two film formation surfaces of the film substrate 1. In one example, the substrate holder may be configured to hold the edges of the film substrate 1 between two frames. In another example, the substrate holder may be a tray having an opening that exposes the film formation surfaces.

The cooling unit 20 has a double-layer structure. Instead, the cooling unit 20 may have a single-layer structure.

The transport passage 18 is configured to support one side (bottom portion) of the substrate holder 14, to which the film substrate 1 is attached, when transporting. Instead, the transport passage may be configured to support the frame 16 of the substrate holder 14 when transporting the film substrate 1 located in a horizontal position. In this case, the transport passage includes, for example, two transport rails, which support the frame 16, and has a structure capable of locating the opening Z of the substrate holder 14 proximate to the cooling unit 20.

The cathode unit 40 may have a structure that differs from that described above. In one example, the magnetic circuits 44 may be omitted from the cathode unit 40. In another example, the cathode unit 40 may include a plurality of targets.

In the above embodiments, the entire cooling mechanism 25 is shifted by the shift mechanism 60. However, at least the cooling unit 20 only needs to be shifted between the cooling position and the retracted position. The shift mechanism 60 may be located, for example, in the chamber 11.

In the above embodiments, the cooling source is embodied in the cryopump 22. Instead, another device such as a freezer may be used.

The cooling unit 20 may include an alignment mechanism that positions the cooling unit 20 relative to the film substrate 1. For example, a pin may be arranged on a corner of the cooling unit 20 to come into contact with the film substrate 1. This adjusts the relative distance between the cooling unit 20 and the film substrate 1. In this case, the position of the film substrate 1 that comes into contact with the pin preferably excludes the clean region. Additionally, the chamber 11 may accommodate an alignment chamber that stops the movement of the cooling unit 20 at the cooling position.

In the above embodiments, the process gas is supplied to the plasma generation space S only through the cooling unit 20. However, in addition to the gas supply system, which supplies the process gas from the cooling unit 20, a gas supply mechanism may be arranged to supply the process gas to the chamber 11.

In the above embodiments, the substrate processing apparatus 10 is embodied in a sputtering device but may be embodied in a different device. The substrate processing apparatus may be a reverse sputtering device, which attracts positive ions from a plasma to a substrate to remove collected matter from the substrate through sputtering. Alternatively, the substrate processing apparatus may be a device that processes a surface, for example, through ion bombardment performed by an ion gun.

The film substrate 1 may be formed from a material other than a resin. The film substrate may be, for example, a rigid substrate such as a paper phenol substrate, a glass epoxy substrate, a Teflon substrate (Teflon is a registered trademark), a ceramic substrate formed from alumina or the like, or a low-temperature co-fired ceramic (LTCC) substrate. Alternatively, a print circuit board formed by forming a metal wiring layer on the above substrates may be used.

The substrate processing apparatus may process a substrate other than a thin substrate such as the film substrate 1. When a substrate that prefers film formation at a relatively low temperature is subject to the process, the advantages of the above embodiments are obtained.

1. A substrate processing apparatus comprising:
a plasma generation unit that generates a plasma from a process gas in a plasma generation space in which a substrate is placed;
a cooling unit opposed to the substrate with a cooling space located in between, wherein the cooling unit includes a supply port that supplies the process gas to the cooling space;
a process gas supply unit that supplies the process gas to the cooling unit; and
a communication portion that communicates the cooling space and the plasma generation space to supply the process gas, which has been supplied to the cooling space, to the plasma generation space.

2. The substrate processing apparatus according to claim 1, wherein
the cooling unit includes a base that includes a gas channel, wherein the gas channel includes the supply port, and
the substrate processing apparatus further comprises a cooling source connected to the base.

3. The substrate processing apparatus according to claim 1, wherein
the cooling unit includes a substrate-opposing surface, and
the supply port is one of a plurality of supply ports symmetrically arranged about a center point of the substrate-opposing surface.

4. The substrate processing apparatus according to claim 1, wherein
the cooling unit includes a rectangular substrate-opposing surface,
the substrate-opposing surface includes a plurality of regions defined by a diagonal line, and
the supply port has the same open area in each of the regions.

5. The substrate processing apparatus according to claim 1, further comprising a frame-shaped substrate holder that holds the substrate,
wherein the cooling unit includes a substrate-opposing surface that is smaller than an opening defined in an inner side of the substrate holder.

6. The substrate processing apparatus according to claim 1, further comprising a frame-shaped substrate holder that holds the substrate, wherein
the substrate holder includes a frame and a substrate fastener, wherein the substrate fastener is arranged on the frame to fasten the substrate, and
the substrate fastener is configured to form a gap between the frame and the substrate so that the substrate fastener allows the process gas to be supplied from the cooling space to the plasma generation space through the gap.

7. The substrate processing apparatus according to claim 1, wherein
the cooling unit includes a substrate-opposing surface and ribs, wherein the ribs project from the substrate-opposing surface, and
the substrate processing apparatus further comprises a communication port located between the ribs to supply the process gas from the cooling space to the plasma generation space.

8. A substrate processing method comprising:
placing a substrate in a plasma generation space; and
processing the substrate while cooling the substrate by supplying a process gas to a cooling space from a cooling unit that is opposed to the substrate with the cooling space located in between, wherein the substrate is processed by supplying the process gas, which has been supplied to the cooling space, to the plasma generation space through a gap formed between the substrate and the cooling unit and generating a plasma from the process gas.
